(19) United States
(12) Patent Application Publication
(10) Pub. No.: US 2024/0306401 A1
(43) Pub. Date: Sep. 12, 2024

(54) METHOD OF MANUFACTURING AN ELECTRONIC CHIP COMPRISING A MEMORY CIRCUIT

(71) Applicant: STMicroelectronics International N.V., Geneva (CH)

(72) Inventors: Remy BERTHELON, Crolles (FR); Olivier WEBER, Grenoble (FR)

(73) Assignee: STMicroelectronics International N.V., Geneva (CH)

(21) Appl. No.: 18/587,606

(22) Filed: Feb. 26, 2024

(30) Foreign Application Priority Data
Mar. 6, 2023 (FR) 2302064

(51) Int. Cl. H10B 63/00; H10B 63/10

(52) U.S. Cl. CPC H10B 63/32; H10B 63/10; H10B 63/80

(57) ABSTRACT

The present disclosure relates to a process that includes the simultaneous formation of a first transistor in and on a first region of a substrate, of a second transistor in and on a second region of the substrate, of a third transistor in and on a third region of the substrate and of a memory cell in and on a fourth region of the substrate. The method includes the following successive steps: forming a first gate stack on the first region, a second gate stack on the second region, a third gate stack on the third region and a fourth stack on line with the fourth region; simultaneously etching a part of the third gate stack and the fourth stack the first and the second gate stacks being protected with a first mask; and simultaneously etching the first and the second gate stacks, the third gate stack and the fourth region of the semiconductor substrate being protected with a second mask.

### CROSS-REFERENCE TO RELATED APPLICATION(S)

This application claims the priority benefit of French patent application number 2302064, filed on Mar. 6, 2023, entitled “Procédé de fabrication d′une puce électronique comprenant un circuit mémoire” which is hereby incorporated by reference to the maximum extent allowable by law.

### BACKGROUND

### Technical Field

The present disclosure relates generally to the field of electronic chips and more specifically deals to electronic chips comprising a memory circuit based on a phase change material and their manufacturing processes.

### Description of the Related Art

A phase change material is a material capable of changing crystalline state under the action of heat and more particularly to commute between a crystalline state and an amorphous state that is more resistive than the crystalline state. This phenomenon is used to define two memory states, for example 0 and 1, differentiated by the resistance as measured across the phase change material.

There is a desire to improve electronic chips having a memory circuit comprising memory elements based on a phase change material and their manufacturing processes.

### BRIEF SUMMARY

The present disclosure provides a method for the simultaneous formation, in and on a semiconductor substrate:
of a first transistor of a first type in and on a first region of the semiconductor substrate;
of a second transistor of a second type in and on a second region of the semiconductor substrate;
of a third transistor of a third type in and on a third region of the semiconductor substrate; and
of a memory cell based on a phase change material in and on a fourth region of the semiconductor substrate.

The method comprising the following successive steps:
a) manufacturing isolation trenches in the fourth region of the semiconductor substrate;
b) forming:
   a first gate stack on and in contact with the first region of the semiconductor substrate,
   a second gate stack on and in contact with the second region of the semiconductor substrate,
   a third gate stack on and in contact with the third region of the semiconductor substrate, and
   a fourth stack on and in contact with the semiconductor substrate in line with the fourth region of the semiconductor substrate;
c) simultaneously etching a part of the third gate stack and the fourth stack in order to expose the semiconductor substrate in its fourth region, the first and the second gate stacks being protected with a first mask; and
d) simultaneously etching the first and the second gate stacks, the third gate stack and the fourth region of the semiconductor substrate being protected with a second mask.

According to an embodiment, the fourth stack is identical to the third gate stack.

According to an embodiment, the process comprises, after the step d), steps of epitaxy of the semiconductor substrate in line with the first and second regions of the semiconductor substrate, the third gate stack and the fourth region of the semiconductor substrate being protected with the second mask.

According to an embodiment, the third gate stack comprises a first gate insulator layer and a gate layer.

According to an embodiment, the first gate stack comprises a dielectric stack, a metal stack and a gate layer.

According to an embodiment, the second gate stack comprises a second gate insulator layer, a dielectric stack, a metal stack and a gate layer.

According to an embodiment, the dielectric stack comprises a first dielectric layer and a second dielectric layer, the second dielectric layer being made of a high permittivity material.

According to an embodiment, the isolation trenches are filled with an oxide.

According to an embodiment, the method comprises a step of manufacturing memory cells in and on the semiconductor substrate in line with the fourth region of the semiconductor substrate.

Another embodiment provides an electronic chip with a memory circuit comprising a first semiconductor layer on and in contact with a second semiconductor layer doped with a first type of conductivity, with said layer on and in contact with a third semiconductor layer doped with a second type of conductivity opposite to the first type of conductivity, the first semiconductor layer comprising zones doped with the second type of conductivity, the memory circuit comprising trenches that delimit the zones of the first semiconductor layer and that extend from a face of the first semiconductor layer opposite to the second semiconductor layer through the first semiconductor layer and lead to the second semiconductor layer, and the zones of the first semiconductor layer being overlayered by memory elements based on a phase change material, the second layer, the third layer and the zones of the first layer constituting bipolar transistors.

According to an embodiment, the electronic chip additionally comprising a first transistor of a first type in and on a first region of the semiconductor substrate, a second transistor of a second type in and on a second region of the semiconductor substrate, a third transistor of a third type in and on a third region of the semiconductor substrate.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1A and FIG. 1B illustrate two partial and schematic cross-section views of an example of electronic chip;

FIG. 2 illustrates a partial and schematic cross-section view of an electronic chip according to an embodiment; and

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, FIG. 3N, FIG. 3O, FIG. 3P, FIG. 3Q, FIG. 3R, FIG. 3S and FIG. 3T illustrate an example of a manufacturing method of the electronic chip as in FIG. 2.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, the operations and elements that are useful for an understanding of the embodiments described herein have been illustrated and described in detail. Manufacturing steps of phase change memory elements have not been described in detail, since the described embodiments are compatible with usual manufacturing steps of phase change memory elements.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify, for example, within 10%, and preferably within 5%.

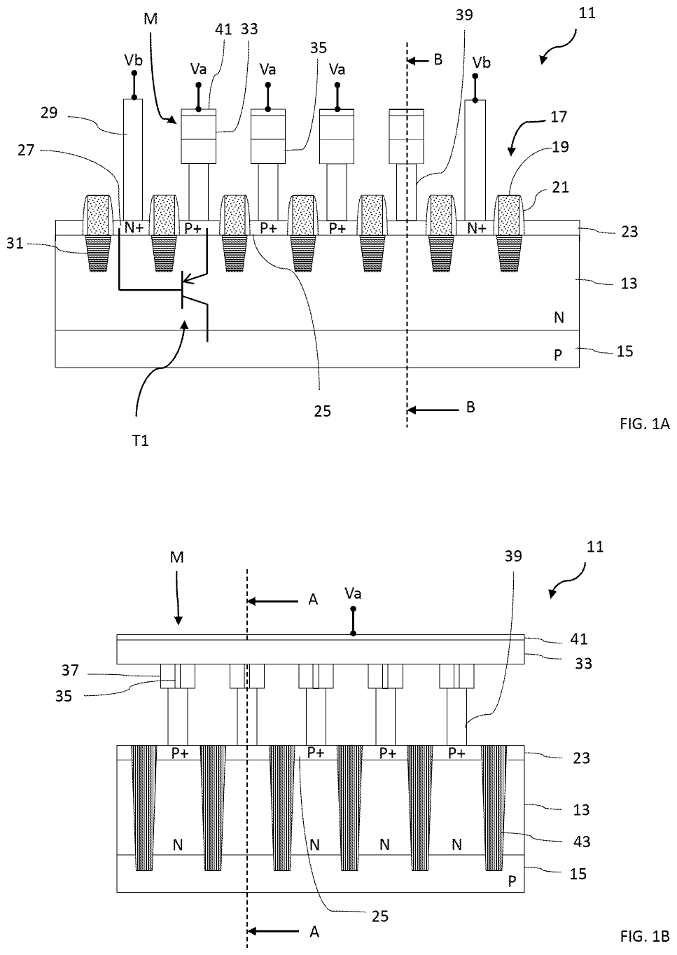

The FIG. 1A and the FIG. 1B illustrate two partial and schematic cross-section views of an example of electronic chip 11, where the FIG. 1A is along the cross-section plane AA of the FIG. 1B and the FIG. 1B is along the plane BB of the FIG. 1A.

More specifically, the FIG. 1A and the FIG. 1B illustrate a part of the electronic chip 11, more precisely a part of a memory circuit of the electronic chip 11. As an example, the electronic chip 11 comprises, in a non-illustrated part, a logic circuit adjacent to the memory circuit. The logic and memory circuits are, for example, manufactured concurrently in and on the same semiconductor substrate.

The electronic chip 11 comprises memory elements M that are organized, for example, as an array of rows and columns, when viewed from above. As an example, the memory elements M illustrated in the FIG. 1A are memory elements M of a same row, while the memory elements illustrated in the FIG. 1B are memory elements of a same column. Rows and columns are respectively called wordlines and bitlines, each memory element M being located at the intersection of a wordline and a bitline. In the FIG. 1A, four bitlines are represented and in the FIG. 1B, five wordlines are represented. However, from a practical point of view, a memory circuit may comprise numbers of bitlines and wordlines different respectively from four or five, for example higher than four and five.

As an example, the memory elements M are made of a phase change material 33, for example based on a chalcogenide material, for example a germanium, antimony and tellurium alloy (GeSbTe), called GST. In each memory element, the phase change material, for example, is monitored by a metallic resistive heating element 35 located under the phase change material, for example in contact, through its upper side, with the lower side of the phase change material 33, and laterally surrounded by a thermal insulator 37. The phase change material 33 is, for example, topped with metal platings 41, for example of a conducting material. As an example, in each memory element M, the metal elements 35 and 41 respectively constitute a lower electrode and an upper electrode of the variable resistance resistive element made of the phase change material 33. As an example, the memory elements M of a same bitline are topped with the same metal plating 41. In other words, the upper electrodes 41 of the memory elements M of a same bitline are interconnected. The metal platings 41 are, for example, coupled to voltage application nodes Va.

The chip 11 comprises a semiconductor layer 13 doped with a first type of conductivity, for example N-type conductivity, for example doped with arsenic or phosphorus atoms. The layer 13 is, for example, made of silicon. The layer 13 lies on a semiconductor layer 15 doped with a second type of conductivity opposite to the first type of conductivity, for example P-type, for example doped with boron atoms. The layer 15 is, for example made of silicon.

As an example, the chip 11 comprises gate patterns 17 (called “dummy gates”) on the upper side of the layer 13, for example extending lengthwise in the direction of the bitlines. The gate patterns 17 comprise, for example, a central part 19 laterally surrounded by spacers 21. The central part 19 of each gate pattern 17 is, for example, made of a semiconductor material, for example of silicon, for example of polycrystalline silicon. The spacers 21 are for example made of an electrically insulating material, for example of a silicon nitride.

In this example, viewed from above, the gate patterns 17 extend between the bitlines of the array of memory elements M. In other words, in this example, viewed from below, any two consecutive bitlines of the array of memory elements M are separated from each other by one gate pattern 17 that extends all along the entire length of said bitlines. Gate patterns 17 are for example laterally separated by a semiconductor layer 23, for example formed by epitaxy from the upper side of the layer 13. The layer 23 is for example made of silicon, for example of monocrystalline silicon. As an example, each memory element M is linked, for example is connected, to the layer 23 through a via 39. As an example, the via 39 is in contact, through its upper side, with the lower side of the heating resisting item 35 of the memory element M. The via 39 is for example in contact, through its lower side, with the upper side of the layer 23.

The layer 23 comprises, for example, first regions 25, for example doped with the second type of conductivity, for example P-type conductivity, that extend between some gate patterns 17 vertically aligned with the memory elements M of the array. For example, the regions 25 are more doped than the layer 15. For example, each region 25 is topped with a memory element. As an example, for each memory element M, the corresponding via 39 electrically couples the heating element 35 of the memory element to the region 25 directly below.

The layer 23 comprises, in addition, second regions 27, for example doped with the first type of conductivity, for example N-type conductivity, that extend between other gate patterns 17. For example, the regions 27 are more heavily doped than the layer 13. For example, contrarily to the regions 25, the regions 27 are not topped with memory elements M but with connection vias 29. The vias 29 provide connections between wordlines. As an example, within a same wordline, two vias 29 are separated by, for example, four memory elements M (that belong respectively to four consecutive bitlines). As an example, the contacts are linked to a voltage application node of a voltage Vb applied to the relevant wordline.

For example, the regions 27 and 25 are laterally delimited by the gate patterns 17 and by isolation trenches 31, for example by super shallow trench isolations (SSTI). For example, the isolation trenches 31 prevent current leaks between two successive bitlines. For example, the trenches 31 are then located under the gate patterns 17. As an example, the trenches 31 are linear and each gate pattern is located on and in contact with a trench 31. As an example, each trench 31 extends lengthwise in the direction of the bitlines, along the entire length of the bitlines. As an example, the trenches 31 extend vertically, in the layer 13, from the upper side of the layer 13 through a part of the thickness of the layer 13. For example, the isolation trenches 31 are filled with a dielectric material, for example silicon oxide. For example, the thickness of the trenches 31 is between 20 nm and 40 nm.

As an example, the chip 11 comprises isolation trenches 43, for example shallow trench isolations (STI). For example, the isolation trenches 31 and 43 are orthogonal to each other and form a gate. For example, the thickness of the trenches 43 is greater than the depth of the trenches 31. For example, the trenches 43 extend from the upper side of the layer 13 through the layer 13 and through a part of the layer 15. As an example, the trenches 43 make it possible to separate, hence to electrically isolate, bands of the layer 13 vertically aligned with respectively each wordline. As an example, each trench 43 extends lengthwise in the direction of the wordlines, along the entire length of the wordlines. For example, the isolation trenches 43 are filled with a dielectric material, for example silicon oxide. For example, the depth of the trenches 43 is between 300 nm and 400 nm.

In the example of FIGS. 1A and 1B, for each memory element M, the zone 25 vertically aligned with the memory element, the layer 13 (and the zone 27) and the layer 15 define a bipolar transistor T1, in this case of PNP-type, for selection of the memory element. For example, each memory element M is associated with a bipolar transistor T1. In this example, the region 25 constitutes an emitting region of the transistor T1, the region 13 (and the zone 27) constitutes a base region of the transistor T1 and the layer 15 constitutes a collector region of the transistor T1. As an example, the collector is common to all transistors T1 of the array and, for example, is connected to the ground. In this example, the base region 13 is common to all transistors T1 of a same wordline of the memory circuit.

Although gate patterns 17 reduce the leakage currents by laterally separating the zones 27, they may create some issues in the memory circuit. Indeed, when a gate pattern 17 extends above an isolating trench 31, it covers orthogonally extending isolation trenches 43. Since the isolation trenches 3 and 43 can have different depths, the gate patterns 17 may warp at the intersection of an isolating trench 31 and an isolating trench 43, which can generate some poor encapsulation of the titanium nitride that generally forms at the surface of the isolation trenches 31 and 43 and can generate parasitic currents.

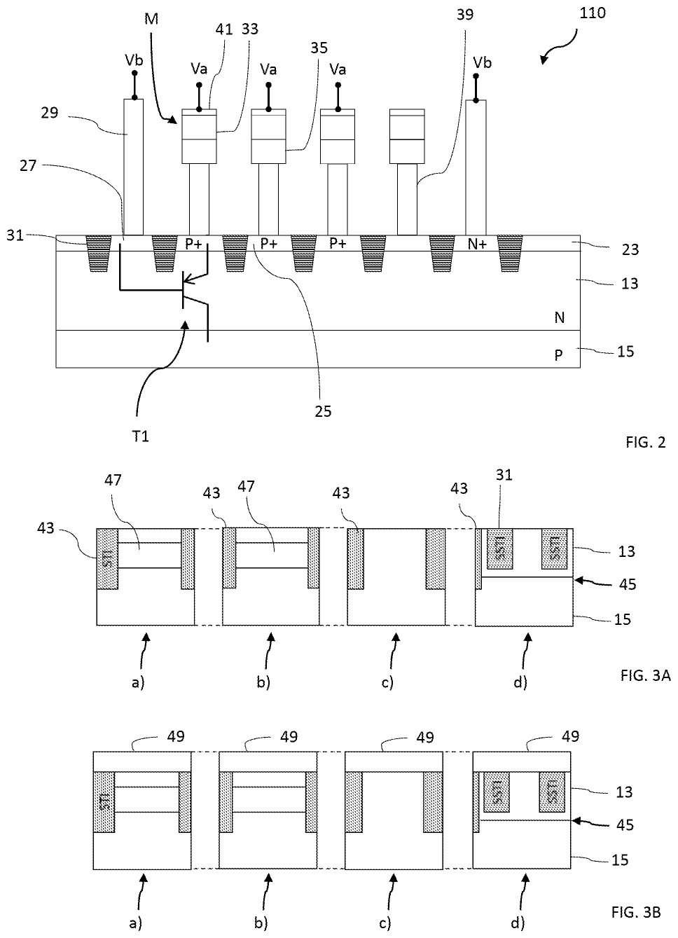

The FIG. 2 illustrates a partial and schematic cross-section view of an electronic chip 110 according to an embodiment.

More specifically, the FIG. 2 illustrates an electronic chip 110 similar to the electronic chip 11 as illustrated in the FIG. 1A, although the electronic chip 110 does not comprise any gate pattern 17.

The electronic chip 110 also differs from the electronic chip 11 in that the electronic chip 23 does not comprise, in the memory circuit, any epitaxied semiconductor layer 23 and in that the zones 27 and 25 are made in the semiconductor layer 13.

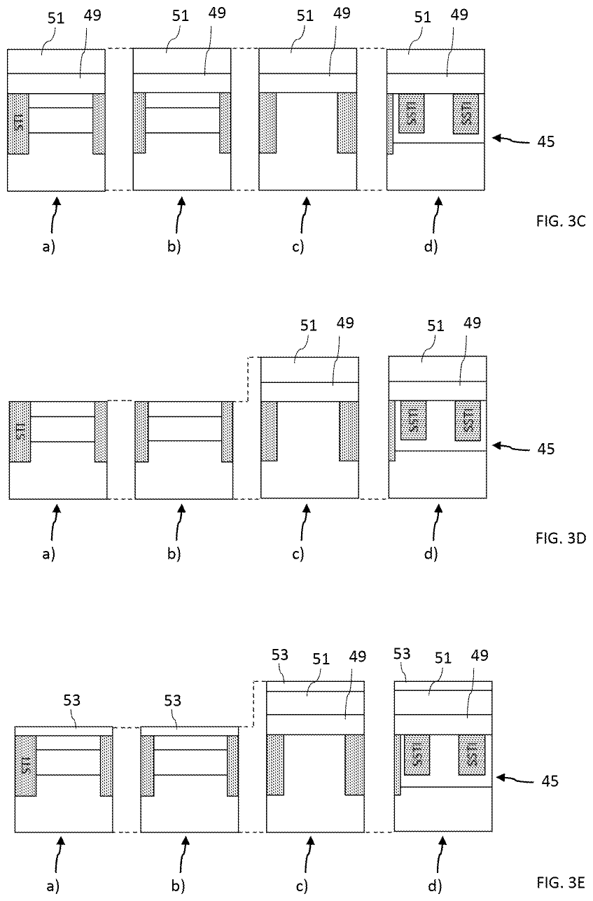

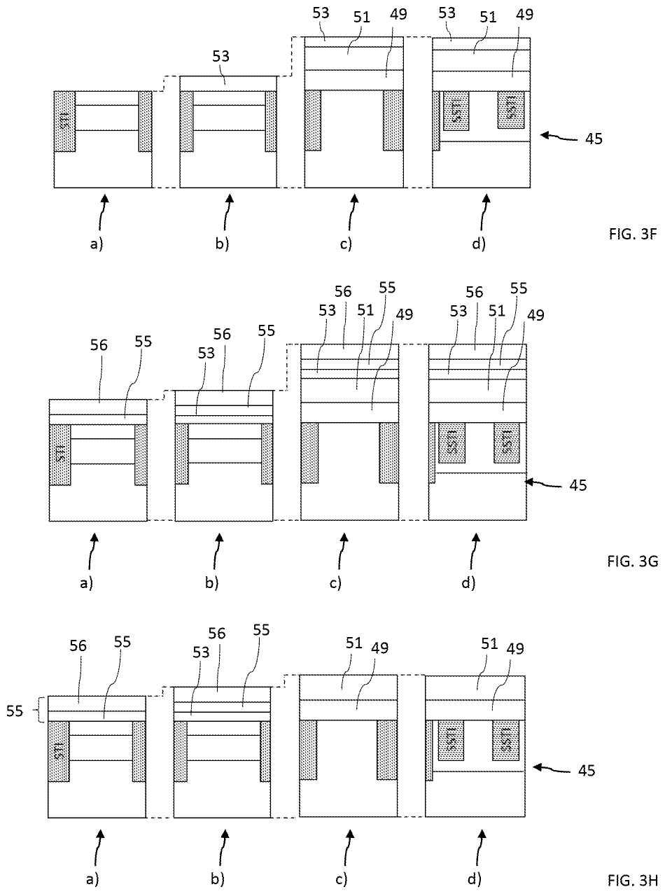

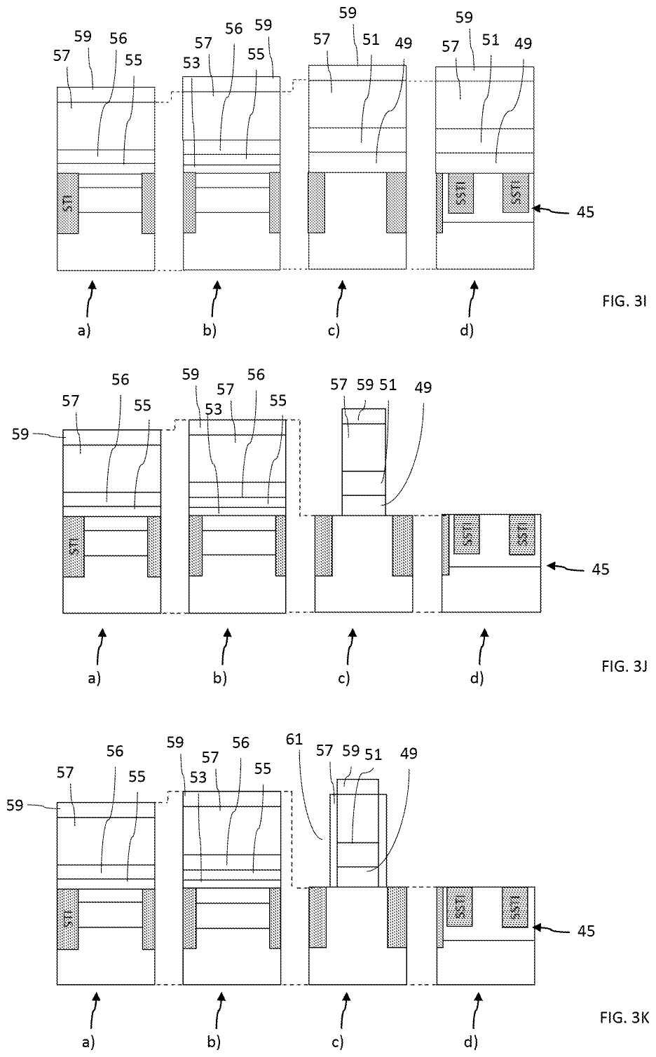

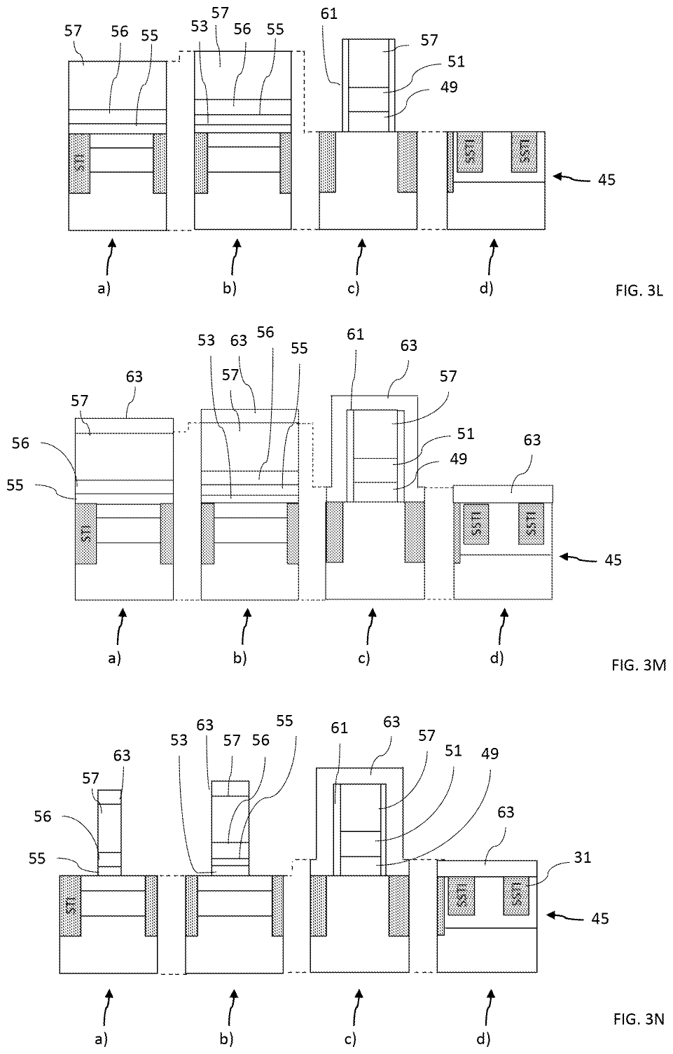

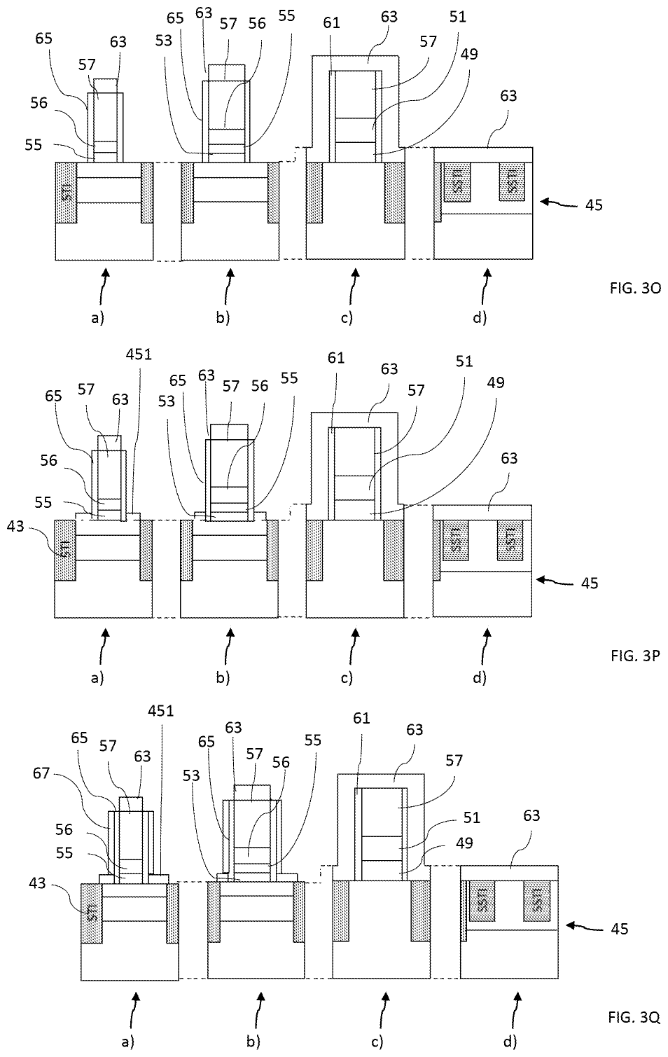

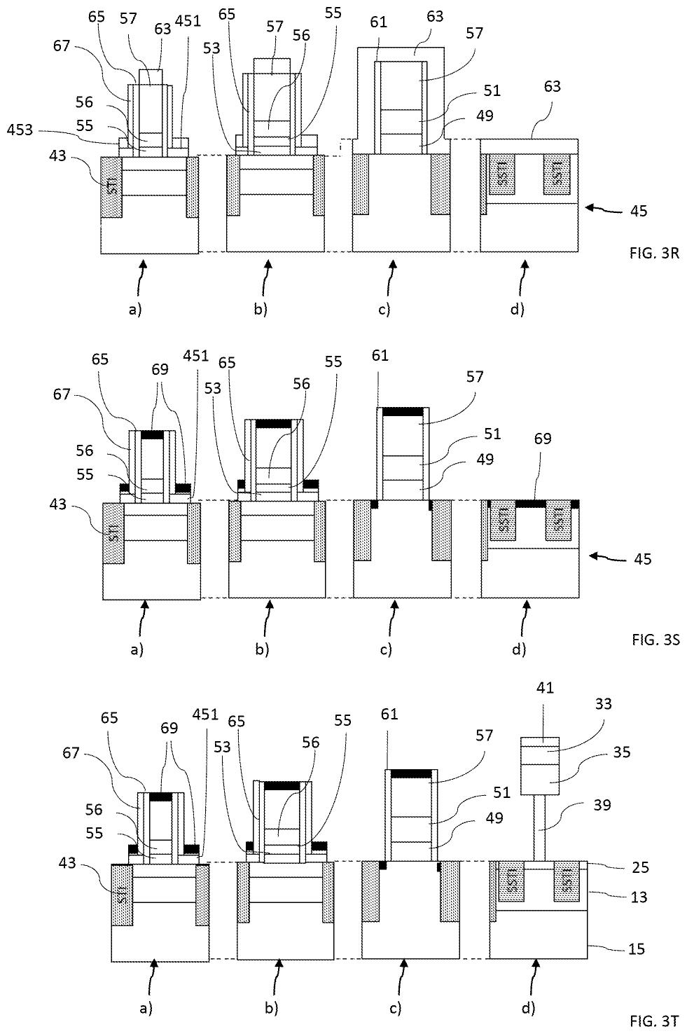

The FIG. 3A, the FIG. 3B, the FIG. 3C, the FIG. 3D, the FIG. 3E, the FIG. 3F, the FIG. 3G, the FIG. 3H, the FIG. 3I, the FIG. 3J, the FIG. 3K, the FIG. 3L, the FIG. 3M, the FIG. 3N, the FIG. 3O, the FIG. 3P, the FIG. 3Q, the FIG. 3R, the FIG. 3S and the FIG. 3T illustrate an example of a manufacturing method of the electronic chip illustrated in FIG. 2.

More particularly, the FIGS. 3A to 3T illustrate a process of concurrent manufacture or co-integration in the same chip of integrated circuits, of the memory circuit of the chip 110 as illustrated in the FIG. 2 having memory cells made of a phase change material and of logical circuits adjacent to the memory circuit with three different types of transistors respectively called GO1, GO2 and GO3. The transistors of type GO1, GO2 and GO3 differ from each other, in particular by the thickness of their gate insulator layer. More specifically, the GO1-type transistors have a gate insulator layer thinner than that of the GO2-type transistors, and the GO2-type transistors have a gate insulator layer thinner than that of the GO3-type transistors. As an example, the GO3 transistors have an operating voltage of between 3V and 5V.

On each of the FIGS. 3A to 3T are illustrated four regions a), b), c) and d) of the chip, in which have been manufactured respectively a GO1-type transistor, a GO2-type transistor, a GO3-type transistor and a memory cell made of a phase change material. In practice, it should be understood that the region a) can comprise several GO1-type transistors, the region b) can comprise several GO2-type transistors, the region c) can comprise several GO3-type transistors, and the region d) can comprise several memory cells made of a phase change material.

The FIG. 3A illustrates an initial structure comprising a conducting substrate 45. In the FIG. 3A, the substrate 45 comprises four regions, more specifically, a first region a) in and on which has been manufactured a GO1-type transistor during the process described below, a second region b) in and on which has been manufactured a GO2-type transistor during the process described below, a third region c) in and on which has been manufactured a GO3-type transistor during the process described below and a fourth region d) in and on which has been manufactured the memory cell during the process described below.

As an example, the semiconductor substrate 45 is made of silicon.

As an example, the semiconductor substrate 45 comprises a buried isolation layer 47 in its first a) and its second b) regions. For example, the layer 47 is made of an oxide, for example silicon dioxide (SiO₂).

As an example, the semiconductor substrate 45 comprises, in addition, the N-type doped semiconductor layer 13 and the P-type doped semiconductor layer 15 in its fourth region d).

The initial structure in the FIG. 3A comprises, for example, isolation trenches, and for example, super shallow isolation trenches 31 and shallow isolation trenches 43. The super shallow isolation trenches 31 extend into the semiconductor substrate 45 to a smaller depth than the shallow isolation trenches 43.

As an example, there are shallow isolation trenches 43 in the first a) and second b) regions of the substrate 45 that extend across, for example, the buried isolation layer 47. As an example, the isolation trenches 43 in the regions a) and b) of the substrate 45 make it possible to delimit and individually isolate the transistors GO1 and GO2 manufactured in and on the substrate 45.

Similarly, as an example, there are shallow isolation trenches 43 in the third c) region of the substrate 45. As an example, the isolation trenches 43 in the region c) of the substrate 45 make it possible to delimit and individually isolate the transistors GO3 manufactured in and on the substrate 45.

As an example, the substrate 45 comprises, in addition, in its fourth region d), isolation trenches 43 and 31 forming a gate similarly to what is disclosed in relation with the FIG. 2.

The FIG. 3B illustrates a structure resulting from a manufacturing step of a first gate isolation layer 49 on the upper side of the structure of FIG. 3A.

For example, during this step, the layer 49 is manufactured on and in contact with the upper side of the substrate 45. For example, the gate isolator layer 49 extends continuously over the whole surface of the substrate 45, notably over the four regions a), b), c) and d) of the substrate 45.

For example, the layer 49 has a substantially constant thickness across the whole surface of the substrate 45. At the end of this step, the gate isolator layer 49 is for example between 6 nm and 16 nm thick, for example between 7 nm and 15 nm thick. As an example, the layer 49 is made of an oxide, for example silicon oxide.

The FIG. 3C illustrates a structure resulting from a manufacturing step of a layer 51, corresponding to a first gate layer, on the upper side of the structure of FIG. 3B.

During this step, the layer 51 is for example manufactured on and in contact with the upper side of the layer 49. For example, the layer 51 continuously extends over the whole surface of the layer 49, notably over the four regions a), b), c) and d) of the substrate 45. As an example, the layer 51 has a substantially constant thickness over the whole surface of the layer 49. As an example, the layer 51 is made of silicon, for example of polycrystalline silicon.

The FIG. 3D illustrates a structure resulting from a step of partial removal of the layers 49 and 51 of the structure of FIG. 3C.

After the formation of the layer 51, the layers 49 and 51 are, for example, locally removed in line with the regions a) and b). As an example, the layers 49 and 51 are removed by etching. In particular, during this step, the layers 49 and 51 are, for example, removed over the entire surface in line with the regions a) and b) in order to expose the upper side of the substrate 45. As an example, at the end of this step, the layers 49 and 51 remain in line with the regions c) and d).

The FIG. 3E illustrates a structure resulting from a manufacturing step of a second gate isolator layer 53 on the upper side of the structure of FIG. 3D.

During this step, the layer 53 is for example manufactured on the upper side of the substrate 45 in line with the regions a) and b) and on the upper side of the layer 51 in line with the regions c) and d). For example, the layer 53 is in contact with the upper side of the substrate 45 in line with the regions a) and b) and with the upper side of the layer 51 in line with of the regions c) and d).

The gate isolator layer 49 extends, for example, continuously over the whole surface of the substrate 45, notably over the four regions a), b), c) and d) of the substrate 45.

For example, the layer 53 has a substantially constant thickness over the whole surface of the structure of FIG. 3D. After this step, the gate isolator layer 45 has a thickness, for example, of between 2 nm and 6 nm, for example of between 3 nm and 5 nm. As an example, the layer 45 is made of an oxide, for example silicon oxide.

The FIG. 3F illustrates a structure resulting from a step of partial removal of the layer 53 of the structure of FIG. 3E.

After the formation of the layer 53, it is, for example, locally removed in line with the region a). As an example, the layer 53 is removed by etching. In particular, during this step, the layer 53 is for example removed from the entire surface in line with the region a) in order to expose the upper side of the substrate 45. As an example, at the end of this step, the layer 53 remains in line with the regions b), c) and d).

The FIG. 3G illustrates a structure resulting from a step of forming an isolating stack 55 and a metal layer 56 on the upper side of the structure of FIG. 3F.

As an example, the stack 55 comprises a first dielectric layer and a second dielectric layer. During this step, the stack 55 is, for example, manufactured on the upper side of the substrate 45 in line with the region a) and on the upper side of the layer 53 in line with the regions b), c) and d). As an example, the stack 55 is in contact with the upper side of the substrate 45 in line with the region a) and with the upper side of the layer 53 in line with the regions b), c) and d).

For example, the metal layer 56 is manufactured on and in contact with the upper side of the stack 55.

The dielectric layers of the stack 55 and the metal layer 56 extend, for example, continuously over the whole surface of the substrate 45, notably over the four regions a), b), c) and d) of the substrate 45.

The dielectric layers of the stack 55 have, for example, a substantially constant thickness over the whole surface of the structure of FIG. 3F. After this step, the stack 55 for example has a thickness of between 0.5 nm and 2 nm, for example of between 1 nm and 1.5 nm.

In addition, the metal layer 56 has, for example, a substantially constant thickness over the whole surface of the structure of FIG. 3F. At the end of this step, the layer 56 for example has a thickness of between 3 nm and 10 nm, for example of between 4 nm and 6 nm.

For example, the stack 55 comprises an oxide, for example silicon dioxide.

For example, the stack 55 comprises a high permittivity material, for example of hafnium silicon oxynitride (HfSiON) and/or hafnium oxide (HfO₂).

As an example, the layer 56 is made of a titanium nitride (TiN).

The FIG. 3H illustrates a structure resulting from a step of partial removal of the layers 55, 56 and 53 of the structure of FIG. 3G.

After the formation of the stack 55 and of the layer 56, they are for example locally removed, along with the layer 53, in line with the regions c) and d). As an example, the layers 55, 56 and 53 are removed by etching. In particular, during this step, the layers 55, 56 and 53 are for example removed from the entire surface in line with the regions c) and d) in order to expose the upper side of the substrate 51. As an example, at the end of this step, the layers 55, 56 and 53 remain in line with the regions a) and b).

The FIG. 3I illustrates a structure resulting from a manufacturing step of a gate layer 57 on the upper side of the structure of FIG. 3H.

During this step, the gate layer 57 is for example manufactured on the upper side of the substrate 56 in line with the regions a) and b) and on the upper side of the layer 51 in line with the regions c) and d). As an example, the layer 57 is manufactured in contact with the upper side of the layer 56 in line with of the regions a) and b) and in contact with the upper side of the layer 51 in line with the regions c) and d). the gate layer 57 extends, for example, continuously over the whole surface of the substrate 45, notably over the four regions a), b), c) and d) of the substrate 45.

The gate layer 57 has, for example, a non-constant thickness over the whole surface of the structure of FIG. 3H, wherein the gate layer 57 is, for example, thicker in line with the region d) of the substrate 45 than in line with the region c) of the substrate 45. At the end of this step, the layer 57 for example has a thickness of between 30 nm and 50 nm, for example of between 35 nm and 45 nm.

As an example, the gate layer 57 is made of silicon, for example of polycrystalline silicon.

As an example, at the end of this step, the structure comprises:
a first gate stack, comprising for example the stack 55, the layer 56 and the layer 57, on and in contact with the upper side of the first region a) of the substrate 45;
a second gate stack, comprising for example the layer 53, the stack 55, the layer 56 and the layer 57, on and in contact with the upper side of the second region b) of the substrate 45;
a third gate stack, comprising for example the layer 49, the layer 51 and the layer 57, on and in contact with the upper side of the third region c) of the substrate 45; and
a fourth stack, comprising for example the layer 49, the layer 51 and the layer 57, on and in contact with the upper side of the fourth region d) of the substrate 45.

In the FIG. 3I, the structure comprises, in addition, a first mask layer 59 on the upper side of the layer 57.

The mask layer 59 is for example deposited on and in contact with the upper side of the layer 57. For example, the first mask layer 59 is made of an oxide, for example silicon dioxide.

The FIG. 3J illustrates the structure resulting from a step of etching of the structure of FIG. 3I.

During this step, the mask layer 59 is locally removed in line with the fourth region d) of the substrate 45 and on a peripheral part in line with the third region c) of the substrate 45.

As an example, at the end of this step, the mask layer 59 is present in line with the regions a) and b) and in line with the central part of the surface of region c).

During this step, in addition, the parts of the structure that are not covered by the mask layer 59 are etched out. Thus, during this step, the stack in line with the region d) and the peripheral part of the stack in line with the region c) are thus etched out. In other words, during this step, the layers 57, 51 and 49 are removed in line with the region d) and a peripheral part of these layers are removed in line with the region c). As an example, these layers are removed in order to expose the upper side of the substrate 45.

During this step, the stacks formed in line with the regions a) and b) are protected by the mask layer 59 and are not therefore etched.

At the end of this step, the part of the stack that remains in line with the region c) matches the gate pattern, comprising the gate and the gate insulator of the transistor GO3.

The FIG. 3K illustrates the structure resulting from a step of manufacturing isolating spacers 61 in the structure of FIG. 3J.

As an example, during this step, the isolating spacers 61 are formed on both sides of the gate patterns in line with the region c) during the step of etching described in relation with the FIG. 3J.

For example, the isolating spacers 61 are made of silicon nitride (Si_{3M4}).

The FIG. 3L illustrates a structure resulting from a step of removing the mask layer 59 in the structure of FIG. 3K.

As an example, during this step, the mask layer 59 is removed in order to expose the upper side of the substrate 57 in the regions a), b) and c).

The FIG. 3M illustrates a structure resulting from a manufacturing step of a second mask layer 63 on the upper side of the structure of FIG. 3L.

More specifically, during this step, the mask layer 63 is for example formed on and in contact with the upper side of the layer 57 in line with the regions a) and b), on and in contact with the upper side of the substrate 45 in line with the region d), and on and in contact with a part of the upper side of the substrate 45, on and in contact with the sides of the spacers 61 and on and in contact with the upper side of the layer 57 in line with the region c).

For example, the mask layer 63 is made of an oxide.

The FIG. 3N illustrates the structure resulting from a step of etching of the structure of FIG. 3M.

During this step, the layer 63 is, in particular, locally removed from a peripheral part in line with the first region a) and from a peripheral part in line with the second region b).

As an example, at the end of this step, the mask layer 63 is present in line with the regions c) and d) and in line with a central part of the surface of the regions a) and b).

During this step, in addition, the parts of the structure that are not covered by the mask layer 63 are etched out. Thus, during this step, the peripheral part of the stack in line with the region a) and the peripheral part of the stack in line with the region b) are etched out. In other words, during this step, the layers 57, 55 and 56 are locally removed from the peripheral part in line with the region a) and the layers 57, 55, 56 and 53 are locally removed from the peripheral part in line with the region d). As an example, these layers are removed in order to expose the upper side of the substrate 45.

At the end of this step, the parts of the stacks remaining in line with the regions a) and b) match the gate patterns of the transistors GO1 and GO2.

During this step, the stack in line with the region c) is protected by the mask layer 63 and is not therefore etched.

During this step, the isolation trenches 31 formed in the region d) of the substrate 45 are protected from etching by the mask layer 63.

The FIG. 3O illustrates the structure resulting from a step of forming isolating spacers 65 in the structure of FIG. 3N.

As an example, during this step, the isolating spacers 65 are formed on both sides of the gate patterns in line with the regions a) and b) during the step of etching described in relation with the FIG. 3N. As an example, since the stack in line with the region c) is protected by the mask layer 63, no spacer 65 is created on its sides.

The isolating spacers 65 are, for example, made of silicon nitride (Si_{3M4}).

The FIG. 3P illustrates a structure resulting from a first step of epitaxy of the substrate 45 of the structure of FIG. 3O.

As an example, during this step, the free silicon parts of the upper side of the structure of FIG. 3O are subjected to epitaxy to create a layer 451 at the surface of the structure of FIG. 3O. For example, the layer 451 is in line with the region a) between the isolation trenches 43 and the stack made of the layers 63, 57, 65, 55 and 56 and the spacers 65. For example, in addition, the layer 451 is in line with the region b) between the isolation trenches 43 and the stack made of the layers 53, 55, 56, 57 and 57 and the spacers 65.

As an example, during this step, since the upper side of the region d) of the substrate 45 is protected by the mask layer 63, the substrate 45 in the region d) does not increase by closing the isolation trenches 31 by their upper sides.

The FIG. 3Q illustrates the structure resulting from a step of forming isolating spacers 67 in the structure of FIG. 3P.

As an example, during this step, the isolating spacers 67 are formed on both sides of the gate patterns in line with the regions a) and b). As an example, since the stack in line with the region c) is protected by the mask layer 63, no spacer 67 is created on its sides.

For example, the isolating spacers 67 are made of silicon nitride (Si_{3M4}).

The FIG. 3R illustrates the structure resulting from a second step of epitaxy of the layer 451 of the structure of FIG. 3Q.

In particular, during this step, the free silicon parts of the upper side of the structure of FIG. 3Q are subjected, for example, to epitaxy to create a layer 453 at the surface of the structure of FIG. 3Q. The layer 453 is thus for example formed in line with the region a) between the isolation trenches 43 and the stack made of the layers 63, 57, 65, 55 and 56 and the spacers 65 and 67. For example, in addition, the layer 451 is formed in line with the region b) between the isolation trenches 43 and the stack made of the layers 53, 55, 56, 57 and 57 and the spacers 65 and 67.

Similarly to what was described in relation with the first epitaxy step, since the upper side of the region d) of the substrate 45 is protected by the mask layer 63, the substrate 45 in the region d) does not increase by closing the isolation trenches 31.

The FIG. 3S illustrates a structure resulting from a step of removing the mask layer 63 and of a silicide in the structure of FIG. 3R.

In particular, during this step, the free silicon parts of the structure of FIG. 3R are subjected, for example, to the formation of silicides in the upper part.

A layer 69 is thus, for example, formed in an upper part of the layer 57 and in an upper part of the layer 453 in line with the region a), in an upper part of the layer 57 and in an upper part of the layer 453 in line with the region b), in an upper part of the layer 57 and in an upper part of the substrate 45 in line with the region c) and in an upper part of the substrate 45 in line with the region d). As an example, the layer 69 is not located vertically aligned with the isolation trenches 43 and 31. As an example, the layer 69 is made of nickel silicide (NiSi).

The FIG. 3T illustrates the structure resulting from a step of manufacturing the memory circuit of the chip 110 in and on the substrate 45 in its fourth region d). As an example, the manufacture of the memory circuit comprises steps of implantation of the zones 25 and 27, of formation of the vias 39 and 29 and of manufacture of the memory elements or memory cells M made of a phase change material. These steps have not been detailed, since the described embodiments are compatible with usual manufacturing processes for memory cells made from phase change material.

Compared to the structure of the FIGS. 1A and 1B, an advantage of the described embodiments is that the removal of the gate patterns 17 in the zone of manufacture of the memory cells made of a phase change material makes it possible to reduce the leakage currents in the memory circuit.

Another advantage of the described embodiments is that they take advantage of the mask layer 63 protecting the gate stack of the transistor GO3 in order to protect the surface of the formation region of the memory cells during the etching of the gate stack of the GO1 and GO2 transistors.

Various embodiments and variants have been described. Those skilled in the art will understand that certain features of these embodiments can be combined and other variants will readily occur to those skilled in the art. In particular, the described embodiments are not limited to the examples of materials and to the dimensions mentioned in the present description.

Finally, the practical implementation of the embodiments and variants described herein is within the capabilities of those skilled in the art based on the functional description provided hereinabove.

A method may be summarized as including the simultaneous formation, in and on a semiconductor substrate (45): of a first transistor of a first type (GO1) in and on a first region (a)) of the semiconductor substrate; of a second transistor of a second type (GO2) in and on a second region (b)) of the semiconductor substrate; of a third transistor of a third type (GO3) in and on a third region (c)) of the semiconductor substrate; and of a memory cell based on a phase change material in and on a fourth region (d)) of the semiconductor substrate, the method comprising the following successive steps: a) forming isolation trenches (43, 31) in the fourth region (d)) of the semiconductor substrate; b) forming: a first gate stack on and in contact with the first region (a)) of the semiconductor substrate, a second gate stack on and in contact with the second region (b)) of the semiconductor substrate, a third gate stack on and in contact with the third region (c)) of the semiconductor substrate, and a fourth stack on and in contact with the semiconductor substrate in line with the fourth region (d)) of the semiconductor substrate; c) simultaneously etching a part of the third gate stack and the fourth stack in order to expose the semiconductor substrate (45) in its fourth region, the first and the second gate stacks being protected with a first mask (59); and d) simultaneously etching the first and the second gate stacks, the third gate stack and the fourth region of the semiconductor substrate (45) being protected with a second mask (63).

The fourth stack may be identical to the third gate stack.

The method may include after the step d), steps of epitaxy of the semiconductor substrate (45) in line with the first and second regions of the semiconductor substrate (45), the third gate stack and the fourth region (d)) of the semiconductor substrate being protected with the second mask (63).

The third gate stack may include a first gate insulator layer (49) and a gate layer (57).

The first gate stack may include a dielectric stack (55), a metal layer (56) and a gate layer (57).

The second gate stack may include a second gate insulator layer (53), a dielectric stack (55), a metal layer (56) and a gate layer (57).

The dielectric stack (55) may include a first dielectric layer and a second dielectric layer, the second dielectric layer being made of a high permittivity material.

The isolation trenches (43, 31) may be filled with an oxide.

The method may include a step of forming memory cells in and on the semiconductor substrate (45) in line with the fourth region (d)) of the semiconductor substrate (45).

An electronic chip (110) may be summarized as including a memory circuit comprising a first semiconductor layer (23) on and in contact with a second semiconductor layer (13) doped with a first conductivity type (N), said the second semiconductor layer being positioned on and in contact with a third semiconductor layer (15) doped with a second conductivity type (P) opposite to the first conductivity type (N), the first semiconductor layer (23) comprising zones (25) doped with the second conductivity type, the memory circuit comprising trenches (31) that delimit the zones (25) of the first semiconductor layer (23) and that extend from a face of the first semiconductor layer (23) opposite to the second semiconductor layer (13) through the first semiconductor layer (23) and emerging in the second semiconductor layer (13); and the zones (25) of the first semiconductor layer (23) being overlayered by memory elements (M) based on a phase change material (33), the second layer (13), the third layer (15) and the zones (25) of the first layer (23) constituting a bipolar transistors (T1).

The electronic chip (110) may additionally include a first transistor of a first type (GO1) in and on a first region (a)) of the semiconductor substrate, a second transistor of a second type (GO2) in and on a second region (b)) of the semiconductor substrate, a third transistor of a third type (GO3) in and on a third region (c)) of the semiconductor substrate.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
forming a structure for a first transistor of a first type in and on a first region of a semiconductor substrate;
forming a structure for a second transistor of a second type in and on a second region of the semiconductor substrate;
forming a structure for a third transistor of a third type in and on a third region of the semiconductor substrate;
forming a structure for a memory cell including a phase change material in and on a fourth region of the semiconductor substrate;
forming isolation trenches in the fourth region of the semiconductor substrate;
forming, subsequent to the forming of the isolation trenches,
a first gate stack on and in contact with the first region of the semiconductor substrate,
a second gate stack on and in contact with the second region of the semiconductor substrate,
a third gate stack on and in contact with the third region of the semiconductor substrate, and
a fourth stack on and in contact with the semiconductor substrate in line with the fourth region of the semiconductor substrate;
concurrently etching the fourth stack and a part of the third gate stack in order to expose the semiconductor substrate in the fourth region, the first and the second gate stacks being protected with a first mask during the etching of the fourth stack and the part of the third gate stack; and
concurrently etching the first and the second gate stacks, the third gate stack and the fourth region of the semiconductor substrate being protected with a second mask during the etching of the first and second gate stacks.

2. The method according to claim 1, wherein the fourth stack includes the same layers as the third gate stack.

3. The method according to claim 1, further comprising:
performing epitaxy of the semiconductor substrate in the first and second regions of the semiconductor substrate, the third gate stack and the fourth region of the semiconductor substrate being protected with the second mask during the epitaxy of the semiconductor substrate.

4. The method according to claim 1, wherein the third gate stack includes a gate insulator layer and a gate layer.

5. The method according to claim 1, wherein the first gate stack includes a dielectric stack, a metal layer, and a gate layer.

6. The method according to claim 1, wherein the second gate stack includes a gate insulator layer, a dielectric stack, a metal layer, and a gate layer.

7. The method according to claim 5, wherein the dielectric stack includes a first dielectric layer and a second dielectric layer, the second dielectric layer being made of a high permittivity material.

8. The method according to claim 1, wherein the isolation trenches are filled with an oxide.

9. The method according to claim 1, further comprising:
forming memory cells in and on the semiconductor substrate in the fourth region of the semiconductor substrate.

10. A device comprising:
a semiconductor substrate including:
a first semiconductor layer having a first conductivity type;
a second semiconductor layer on the first semiconductor layer, the second semiconductor layer having a second conductivity type; and
a third semiconductor layer on the second semiconductor layer, the third semiconductor layer including zones doped with the first conductivity type; and
a memory circuit including:
trenches that delimit the zones of the third semiconductor layer, the trenches extending from a face of the third semiconductor layer opposite to the second semiconductor layer, through the third semiconductor layer, and into the second semiconductor layer; and
memory elements overlying the zones of the third semiconductor layer, each of the memory elements including a phase change material, the memory elements including bipolar transistors that include the first semiconductor layer, the second semiconductor layer, and the zones of the third semiconductor layer.

11. The device according to claim 10, further comprising:
a first transistor of a first type in and on a first region of the semiconductor substrate;
a second transistor of a second type in and on a second region of the semiconductor substrate; and
a third transistor of a third type in and on a third region of the semiconductor substrate.

12. The device according to claim 10, further comprising:
a first transistor of a first type having a first gate insulator thickness in and on a first region of the semiconductor substrate;
a second transistor of a second type having a second gate insulator thickness different from the first gate insulator thickness in and on a second region of the semiconductor substrate;
a third transistor of a third type having a third gate insulator thickness different from the first and second gate insulator thicknesses in and on a third region of the semiconductor substrate,
wherein the electronic chip does not include gate patterns above the trenches.

13. A method comprising:
forming first isolation trenches in a first transistor region, a second transistor region, a third transistor region, and a memory cell region of a semiconductor substrate;
forming first and second buried isolation layers in the first and second transistor regions, respectively;
forming second isolation trenches in the memory cell region;
forming a first plurality of gate layers in the first transistor region and on the semiconductor substrate;
forming a second plurality of gate layers in the second transistor region and on the semiconductor substrate;
forming a third plurality of gate layers in the third transistor region and on the semiconductor substrate;
forming a stack of layers in the memory cell region and on the semiconductor substrate;
removing the stack of layers and a portion of the third plurality of gate layers; and
removing portions of the first plurality of gate layers and the second plurality of gate layers.

14. The method of claim 13, wherein the first isolation trenches extend into the semiconductor substrate to a first depth, and the second isolation extend into the semiconductor substrate to a second depth smaller than the first depth.

15. The method of claim 13, wherein the first plurality of gate layers forms a gate of a first transistor of a first type, the second plurality of gate layers forms a gate of a second transistor of a second type, and the third plurality of gate layers forms a gate of a third transistor of a third type.

16. The method of claim 15, wherein
the first plurality of gate layers includes a first insulator, the second plurality of gate layers includes a second insulator, and the third plurality of gate layers includes a third insulator, and
the first, second, and third insulators have different thicknesses.

17. The method according to claim 13, wherein the third plurality of gate layers includes the same layers as the stack of layers.

18. The method according to claim 13, wherein forming the first plurality of gate layers includes:
forming a dielectric stack;
forming a metal layer; and
forming a gate layer.

19. The method according to claim 18, wherein forming the dielectric stack includes:
forming a first dielectric layer; and
forming a second dielectric layer.

20. The method according to claim 13, wherein forming the second plurality of gate layers includes:
forming a gate insulator layer;
forming a dielectric stack;
a metal layer; and
a gate layer.

21. The method according to claim 13, further comprising:
forming a memory cell in the memory cell region and on the semiconductor substrate.
